(19) United States
(12) Patent Application Publication
(10) Pub. No.: US 2022/0014280 A1
(43) Pub. Date: Jan. 13, 2022

(54) METHODS, APPARATUSES, AND SYSTEMS FOR NOISE REMOVAL

(71) Applicant: The Government of the United States, as represented by the Secretary of the Navy, Washington, DC (US)

(72) Inventors: Meredith N. Hutchinson, Washington, DC (US); Jonathan M. Nichols, Crofton, MD (US)

(21) Appl. No.: 17/353,766

(22) Filed: Jun. 21, 2021

Related U.S. Application Data
(60) Provisional application No. 63/041,079, filed on Jun. 18, 2020.

(51) Int. Cl. H04B 15/00; G01R 29/26

(52) U.S. Cl. CPC H04B 15/00; G01R 29/26

(57) ABSTRACT

Methods, apparatuses, and systems for removing noise from a received signal. A signal is received, at a controller, that was recorded by a sensor and emitted by a source. The signal includes a signal of interest component and a noise component. The noise component of the signal is sampled, and the sampled noise component of the signal is used to estimate a variance in the noise component. An energy of the signal of interest component of the signal is determined. A cumulative distribution function for the received signal is calculated, and a cumulative distribution function of the signal of interest component of the received signal is then calculated based on the estimated variance in the sampled noise component, the determined energy of the signal of interest component of the signal, and the calculated cumulative distribution function for the received signal.

### BACKGROUND

### Field of the Invention

The present application relates generally to improved methods of noise removal from recorded signals.

### Description of Related Art

In the real world, noise is present in almost every recorded signal. For example, a recording of a musician playing a piece of music will have background noise from various sources present during the recording such as electrical hums in the room or sounds permeating the walls. When the ratio of the signal of interest (e.g., the sound from the instrument) to the recorded noise, commonly referred to as the signal-to-noise ratio, is low it can be difficult to discern the signal of interest. To a person's ears the beautiful music is mired with noise on the same level. Of course, signal of interests may be come from a variety of sources, not just musicians. But in each of those instances noise is almost always present. While there exist many approaches to reducing noise in recorded signals in the frequency domain, those approaches have drawbacks. Noise removal in the frequency domain can distort the signal and alter the signal properties; it can also be computationally intensive. Thus, it would be preferable to have a technique for noise removal that may be implemented by a computer that improves the speed at which the computer effects noise removal—regardless of what the recorded signal is—while providing for robust and accurate noise removal.

Signals that are free from noise are generally more useful. For example, it is common for signals to be recorded to determine the location and other information (e.g., velocity) of source. For example, a radar gun sends a signal towards an object, e.g., a car, and measures the return of that signal. The returned signal is used to calculate a time delay which can be used to compute the distance to, or the speed of, the object. Signals may also be generated by a source and received at several different locations. The received signals are then used to determine the location of the source. Time delay estimation (TDE) is an important step in the process of source localization. It is known that an emitted signal will travel through a medium and reach one or more spatially distributed sensors or receivers at times that are proportional to the distance traveled. In general, accurate estimates of the relative arrival times will provide accurate estimates of the source location. However, noise is one corrupting influence on the received signals and can affect the accuracy of the source localization technique. Conventional approaches are often tailored to an assumed noise model (e.g., follow the principle of maximum likelihood) and include maximizing the cross-correlation, minimizing the magnitude of the difference between observed and reference signals, and maximizing the average mutual information function. These approaches, however, are themselves computationally intensive and can distort the signal of interest. Thus, it would be beneficial to have methods that could account for noise and other phenomena that might morph the received signal while minimizing the computational requirements of an apparatus or system implementing those techniques.

### SUMMARY OF THE INVENTION

One or more the above limitations may be diminished by structures and methods described herein.

In one embodiment, a method is provided. A signal is received at a controller that was recorded by a sensor and emitted by a source. The signal includes a signal of interest component and a noise component. The noise component of the signal is sampled, and the sampled noise component of the signal is used to estimate a variance in the noise component. An energy of the signal of interest component of the signal is determined. A cumulative distribution function for the received signal is calculated, and a cumulative distribution function of the signal of interest component of the received signal is then calculated based on the estimated variance in the sampled noise component, the determined energy of the signal of interest component of the signal, and the calculated cumulative distribution function for the received signal.

### BRIEF DESCRIPTION OF THE DRAWINGS

The teachings claimed and/or described herein are further described in terms of exemplary embodiments. These exemplary embodiments are described in detail with reference to the drawings. These embodiments are non-limiting exemplary embodiments, in which like reference numerals represent similar structures throughout the several views of the drawings, and wherein:

FIG. 1A is an illustration of a emitted signal and a return signal containing the reflected signal, noise and associated transformations from propagation through a medium;

FIG. 1B is an illustration of a signal emitted by a source being received at a plurality of locations;

FIG. 2A is a block diagram of a system for removing noise from one or more received signals according to one embodiment;

FIG. 2B is a block diagram of an exemplary controller according to one embodiment;

FIG. 3 is a flowchart illustrating a method of calculating a noise-free cumulative distribution function for a signal of interest contained within a received signal;

FIG. 4A is an illustration of a probability density function;

FIG. 4B is an illustration of a cumulative distribution function;

FIG. 4C is an illustration of a cumulative density transform;

FIG. 4D is a plot of total energy of several received signals each with a different signal-to-noise ratio;

FIG. 5A is a plot amplitude versus time for a received signal;

FIG. 5B is a plot of amplitude versus time for another received signal;

FIG. 5C is a plot of cumulative distribution functions for the signals shown in FIGS. 5A and 5B along with their respective noise components;

FIG. 5D is a plot of cumulative distribution functions for the signals of interest after noise correction;

FIG. 6 is a graph of the cumulative distribution transform corresponding to FIG. 5D;

FIG. 7 is a plot of estimated time delay for a variety of estimators as a function of signal-to-noise ratio;

FIG. 8A is another plot of estimate time delay for a variety of estimators as a function of signal-to-noise ratio;

FIG. 8B is a plot of estimated dispersion as a function of signal-to-noise ratio; and

FIG. 9 is a plot of averaged elapsed time to reach a solution for different estimators as a function of signal-to-noise ratio.

Different ones of the Figures may have at least some reference numerals that are the same in order to identify the same components, although a detailed description of each such component may not be provided below with respect to each Figure.

### DETAILED DESCRIPTION OF THE PREFERRED EMBODIMENTS

In accordance with example aspects described herein are systems and methods for reducing noise in recorded signals. This application claims priority to U.S. Provisional Patent Application 63/041,079, filed Jun. 18, 2020, the contents of which are incorporated by reference herein in their entirety.

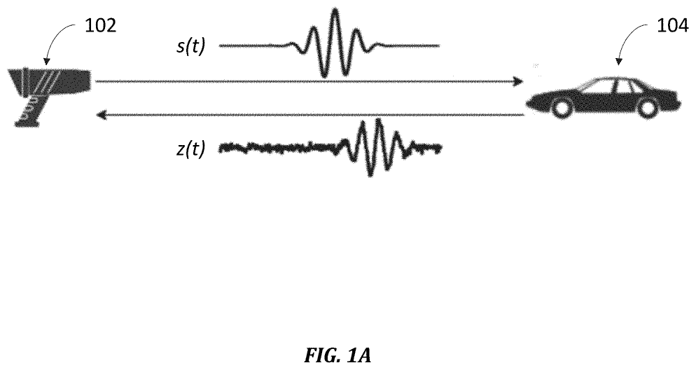

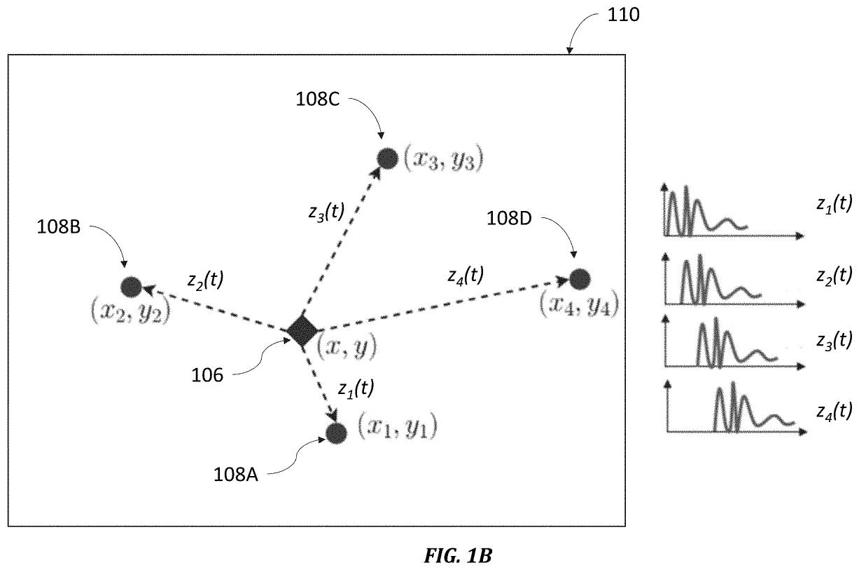

FIG. 1A illustrates the principal of noise in a recorded signal. Here, a source 102 emits a transmitted signal s(t) towards a target 104. At least a portion of the signal s(t) is reflected from the surface of target 104 and returns to source 102 as a return signal z(t). The return signal z(t) includes two components: the signal of interest z_{signal}(t) and noise TKO. FIG. 1B illustrates another example of a noise in a recorded signal. Here, a source 106 located at a position (x, y) emits a signal. The signal may be a naturally occurring signal, such as a p-wave during an earthquake, or an artificial signal (e.g., a piezoelectric transducer creating acoustic waves in a plate). The original signal travels through a medium 110 (e.g., air, earth, or an object) and may be recorded at a plurality of positions. In FIG. 1B, the received signal is recorded at four different positions 108A-D resulting in four different recorded signals z₁(t), z₂(t), z₃(t) and z₄(t) respectively. Of course, the number of positions where the signal is recorded may any number, and thus a signal recorded at an i-th position may be expressed as zᵢ(t), where i≥1. For example, in the case of recording a musical instrument, there may be only a single microphone equipped to record the instrument. But in the case of monitoring seismic waves there may tens or hundreds of seismometers recording vibrations within the Earth.

Obviously, signals may be recorded for a variety of applications. One application, is the task of source localization, where the recorded signals are used to determine the location of the source of the signals. In the field of source localization, the times at which signals zᵢ(t) . . . z_{N}(t) are recorded are very important because it varies based on the respective distances between the source 106 and sensors 108ᵢ . . . 108_{N}. Accurate estimates of the times the signals are recorded is critical to an accurate determination of source location. A noisy signal, however, limits the accuracy of the estimated arrival time of that signal. In addition, the signal may be morphed by the medium 110 through which it passes, and such morphing can affect the ability of a controller to accurately determine the arrival time of the signal. Like above, each of signals z₁(t), z₂ (t), z₃(t) and z₄(t) includes two components: a signal of interest z_{i-signal}(t) and noise ηᵢ(t), where i corresponds to the sensor number.

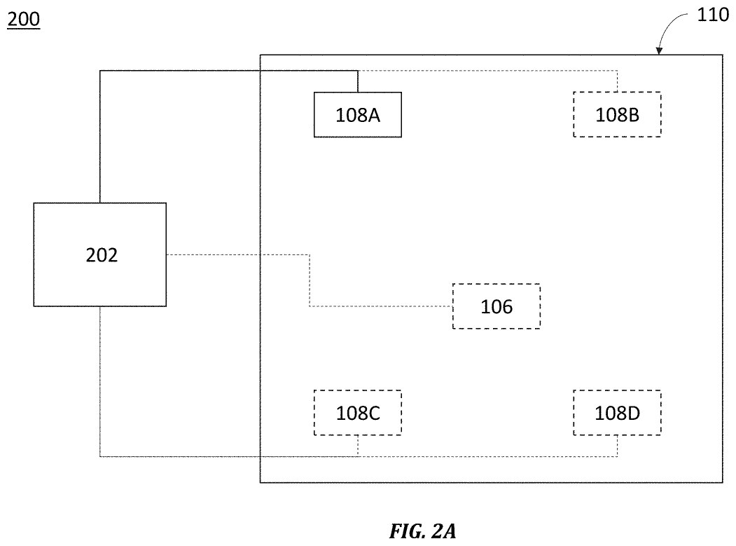

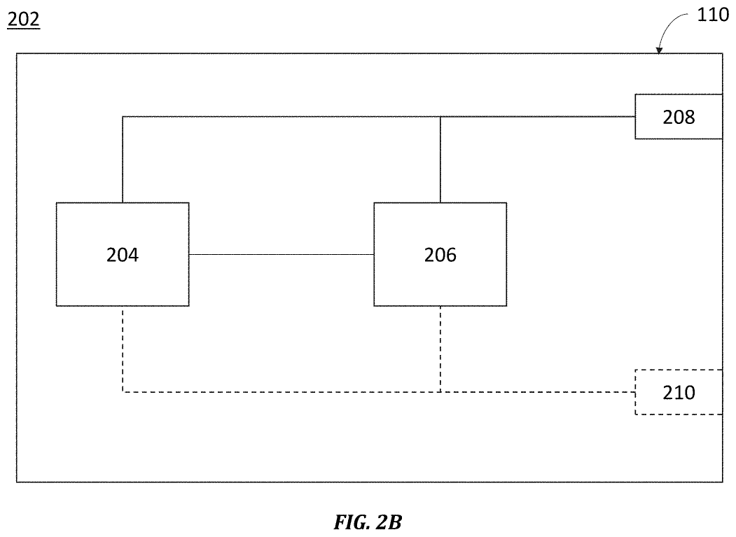

FIG. 2A is a block diagram of a system 200 for processing one or more signals corresponding to one or more sensors 108A, 108B, 108C, and 108D, respectively. As discussed above, the number of sensors may be any number (equal to or greater than one) depending on the application and thus may be generically labelled sensors 108ᵢ. Here, for illustrative purposes, four sensors are shown in FIG. 2B. In FIG. 2A, the signals recorded by sensors 108A, 108B, 108C, and 108D are directly transmitted to a controller 202 for processing. However, this is merely exemplary. The signals may be recorded by sensors 108A, 108B, 108C, and 108D and provided to a different apparatus as bulk data. That data may then be provided to controller 202 for processing without controller 202 ever receiving data directly from sensors 108A, 108B, 108C, and 108D. In this case, it is likely that the raw analog signals from sensors 108A, 108B, 108C, and 108D have been converted into digital signals through a sampling process. In one embodiment, controller 202 may also receive the original signal from the source 106, and use that signal for estimation purposes.

FIG. 2B is a block diagram of a controller 202 for processing signals. The raw signals for sensors 108, may be received through an input/output (I/O) device 208 which may be a: serial connection, USB connection, Bluetooth connection, WiFi connection, Ethernet connection, or other data transfer connection. As mentioned above, the raw signals from sensors 108, may have been received by another device and converted into digital data, which itself may be received through I/O 208 and stored in memory 206 under the control of a central processing unit (CPU) 204. Memory 206 also stores a control program that, when executed by the processor 204, provides for overall control of controller 202 and allows CPU 204, and by extension controller 202, to perform the techniques described here. In one embodiment, CPU 204 may also control sensors 108, through I/O 208. Controller 202 may further include, in one embodiment, a built-in sensor 210 for directly measuring the time varying amplitude of a signal. For example, sensor 210 may be a microphone or a radar receiver. The CPU 204 may receive raw signals or signal data through I/O 208 and/or receive analog signals from sensor 210. While controller 202 has been described above in terms of a computer, some or all of the components in controller 202 may be embodied in an integrated circuit and thus form a microcontroller.

As discussed below in more detail, the noise reduction techniques disclosed herein result in substantial computational savings compared to previous techniques. What the particular signals correspond to (e.g., music, seismic waves, or some other phenomena) is immaterial. The methods described herein are directed to more efficient noise removal techniques and apparatuses that are applicable to a variety of applications and phenomena. The techniques represent a software-based improvement to systems that perform noise removal making them more efficient with comparable—if not better—accuracy. The examples described below for which the noise corrected signals are used are merely exemplary, and provided to show the computational efficiencies of the techniques described herein. Having described in general, the hardware components of a control 202 for reducing noise in a recorded signal, attention will now be directed to exemplary methods for reducing such noise that may be embodied in a computer program stored in memory 206.

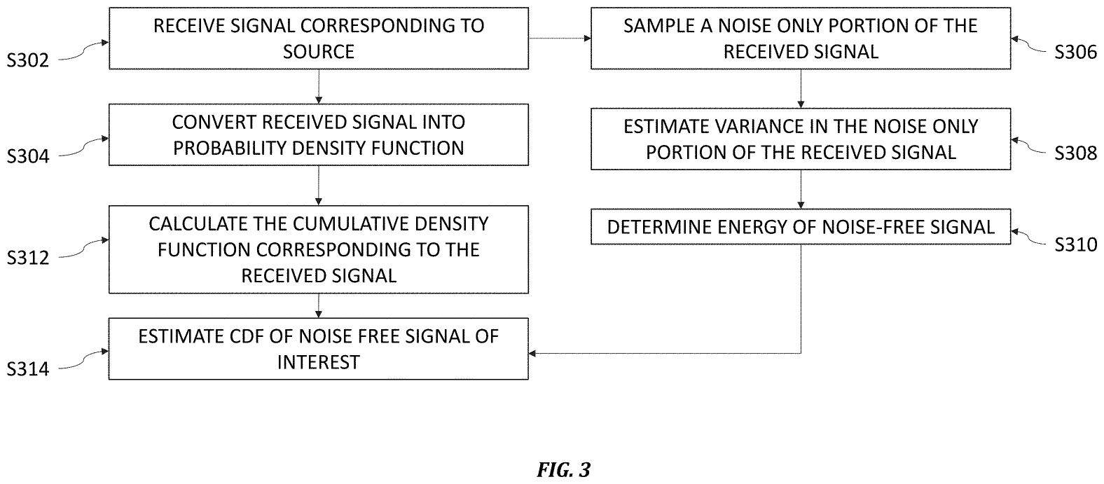

FIG. 3 is a flowchart illustrating a method of reducing noise in a received signal according to one embodiment. Before proceeding into the details of FIG. 3, it is worth describing probability density functions (PDFs), cumulative density functions (CDFs), and cumulative density transforms (CDT) in a qualitative sense, as PDFs, CDFs, and CDTs are used in the techniques described below.

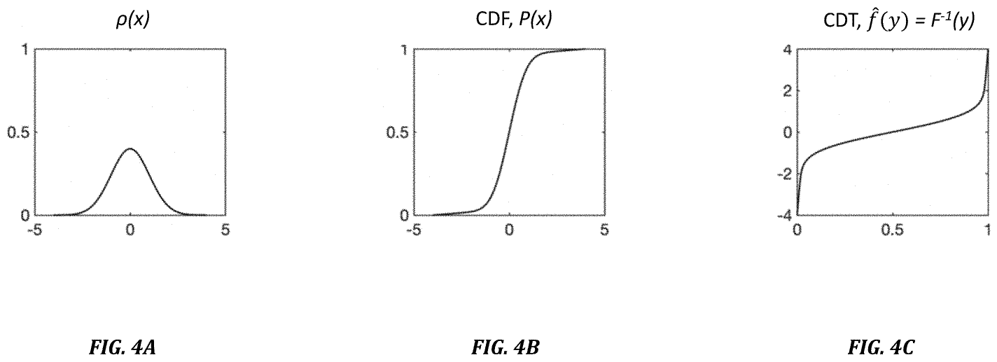

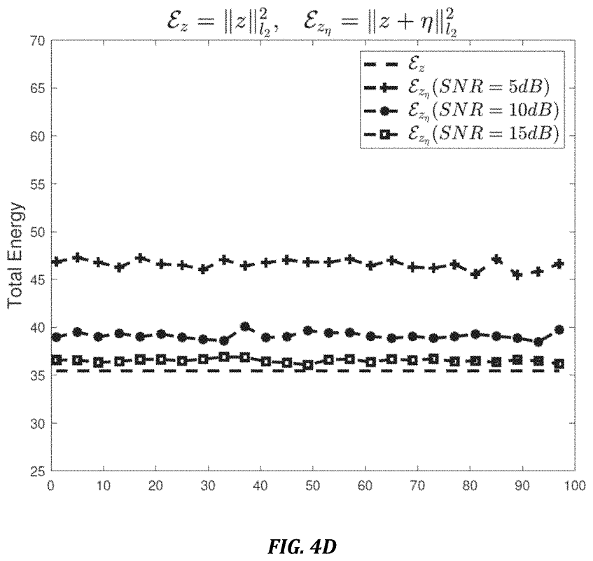

FIG. 4A is a graph showing an exemplary PDF p(x) and is provided for illustrative purposes. A PDF describes that probability that a value x is close to some value X. Thus, if one was buying a pound of rice, the PDF would describe the probabilities of getting slightly less than a pound or slightly more than a pound. If the scale is accurate and the person pouring out the rice is careful, then one would expect the PDF to have a small variance centered on the expected value (i.e., one pound in the example). FIG. 4A depicts a PDF for Gaussian noise values centered on zero. Since the mean of the noise signal is zero, the PDF has its highest value at x=0, with values approaching zero as you move along the abscissa away from 0. FIG. 4B shows the cumulative distribution function (CDF) P(x) corresponding to PDF p(x). In general, the CDF represents the total probability from −∞ to a point x where the CDF is being evaluated. In the case of a set of discrete time values t₁, . . . , t_{N} (like in a digital signal), the CDF represents the total probability from a time t₁ to a time t that is being evaluated. If one evaluates the CDF shown in FIG. 4B at point x=0, the value of the CDF is 0.5. This makes sense intuitively as FIG. 4A shows that the PDF is symmetric about 0, meaning that it is equally likely that the random variable is below the expected value of 0 as it is above. So one would expect the total probability of the random variable being between −5 and 0 to be 50% or 0.5. The CDF at the point x=5 is unity because, as the PDF in FIG. 4A shows, the PDF has gone to zero at that point. In other words, the probability that the random variable is greater than x=5 is zero, and thus the total probability from −5 to 5 is 1. Having conceptually explained the PDF and CDF in FIGS. 4A and 4B, attention will now be directed to the CDT shown in FIG. 4C. As explained in further detail below, the CDT is the inverse of the CDF. The CDT is further explained in “The Cumulative Distribution Transform and Linear Pattern Classification” by Se Rim Park et al., Applied and Computational Harmonic Analysis 2017, the contents of which are incorporated by reference herein in its entirety. Practically, this means that the ordinate and the abscissa are switched such that evaluating the CDT at a point on the abscissa tells you the value at which that summed probability may be found. So if one is evaluating the CDT in FIG. 4C at 0.5, the value on the ordinate will be 0 which, as discussed above, is the point at which half of the random values will be above or below that point. Having described qualitatively the features of PDFs, CDFs, and CDTs, a method for removing noise from a received signal will be discussed in reference to FIG. 3. For simplicity, FIG. 3 describes the processing of single signal; however, as one of ordinary skill will appreciate, the process may be repeated, or done in parallel, by controller 202 for any number of signals.

In S302, a signal z(t) corresponding to a sensor (either one of 108ᵢ or 210) is received at controller 202 and processed by CPU 204. If signal z(t) is an time-varying analog signal, then it is digitally sampled by CPU 204 to create a digital signal z(tᵢ), where i is 1 to N, with N being the number of samples. As one of ordinary skill will appreciate, the sampling rate (and thus the sampling period Δt) will at least satisfy the Nyquist theorem to ensure an accurate digital representation of the analog signals. The length of the desired sample and the sampling rate will determine the value of N. If the received signal is already a digital signal, the CPU 204 skips the sampling step.

As discussed above, the received signal z(t) contains both a signal of interest z_{g}(t) and a noise component η(t). Thus, the received noisy signal may be expressed as:

z_{η}(t)=z_{g}(t)+η(t), where η(t)˜ [symbol] (0, σ²)

Here, an assumption has been made that the noise has a zero mean and a variance of σ². One type of noise fitting this description are independent and identically distributed Gaussian noise values. In S304, the received digital signal z_{η}(t) is converted into a normalized positive probability density function (PDF) r(t) by Equations 1 and 2 below.

$$\begin{matrix}r ( t ) = B ( {z}_{η} ) ( t ) = \frac{{z}_{η}^{2} ( t )}{{‖ {z}_{η} ‖}_{{l}_{2}}^{2}} , t = {t}_{1} , … {t}_{N} & Equation 1 \\ r ( t ) = \frac{{( {z}_{g} ( t ) + η ( t ) )}^{2}}{{ɛ}_{{z}_{η}}} where {ɛ}_{{z}_{η}} = {‖ {z}_{η} ‖}_{{l}_{2}}^{2} & Equation 2\end{matrix}$$

In Equation 2, ε_{z}_{_{η}}=∥z_{η}∥ₗ_{₂}² is the energy of the received (noisy) signal. In terms of a cumulative density function (CDF), Equation 1 may be expanded and written as follows (Equation 3) to obtain a CDF of the noisy signal:

$$R ( t ) = {\int }_{{t}_{1}}^{t} \frac{{( {z}_{g} ( μ ) + η ( μ ) )}^{2}}{{ɛ}_{{z}_{η}}} d μ$$

Taking the expected value over different realizations of the noise, recognizing that the expected value of E[η²]≡σ², one obtains Equations 4 and 5 below:

$$E [ R ( t ) {ɛ}_{z η} ] = {\int }_{{t}_{1}}^{t} {z}_{g}^{2} ( u ) d u + {\int }_{{t}_{1}}^{t} {σ}^{2} d u$$

$$E [ R ( t ) ] = \frac{{ɛ}_{z} {S}_{g} ( t ) + {σ}^{2} ( t - {t}_{1} )}{{ɛ}_{z η}}$$

where

$${S}_{g} ( t ) = {\int }_{{t}_{1}}^{t} \frac{{z}_{g}^{2} ( u )}{{ɛ}_{z}}$$

du is the CDF of the noise-free signal, which we seek to estimate, and ε_{z}=∥z_{g}(μ)∥ₗ_{₂}² is the energy of the noise free signal. In Equation 5, the noisy signal energy ε_{z}_{_{η}} is treated as constant and equal to its mean, i.e., ε_{z}_{_{η}}=E[ε_{z}_{_{η}}]=ε_{z}+σ²(t_{N}−t₁). This approximation is valid as long as the fluctuations in the energy of the received signal are small with respect to expected energy of the received signal. This is often the case, especially for applications where the number of digital samples in the signal being processed is large, as the assumption simply says that fluctuations in the total signal mass among different realizations will be typically small relative to the total signal mass. This is illustrated in FIG. 4D which shows three plots of ε_{z}_{_{η}} with signal-to-noise (SNR) ratios of 5 dB, 10 dB, and 15 dB, along with a plot ε_{z}, the noise-free signal, for 100 realizations of noise. It is self-evident from FIG. 4D that the fluctuations in total energy are small relative to the magnitude of the mean energy even at different SNR ratios.

Equation 5 above can be rewritten to yield the noise-corrected CDF, S_{g}(t) of the signal of interest, as shown below (Equation 6):

$${\tilde{S}}_{g} ( t ) = \frac{E [ R ( t ) ] \{ {ɛ}_{z} + {σ}^{2} ( {t}_{N} - {t}_{1} ) \} - {σ}^{2} ( t - {t}_{1} )}{{ɛ}_{z}}$$

In Equation 3, the term ε_{z}+σ²(t_{N}−t₁) is the expected energy of the noisy signal. Here the independent individually distributed noise, i.i.d, will result, on average, in the addition a straight line to the CDF. By subtracting this “noise CDF” one can account for the additive contribution. Allowing the signal-to-noise ratio (SNR) to be defined as:

$$S N R = \frac{{ɛ}_{z}}{{σ}^{2} ( {t}_{N} - {t}_{1} )} ,$$

then Equation 6 may be rewritten as (Equation 7):

$${\tilde{S}}_{g} ( t ) = \frac{E [ R ( t ) ] [ S N R + 1 ] - \frac{( t - {t}_{1} )}{( {t}_{N} - {t}_{1} )}}{S N R}$$

Thus, in cases where obtaining the SNR is easier, compared to obtaining the energy of the noise free signal and the noise variance, Equation 7 may be preferable. Stepping back for a moment, it is clear that the influence of the additive, i.i.d noise is seen as the addition of a constant slope to the CDF. Under the chosen normalization scheme (by which the PDFs are obtained), this slope is the noise variance. Thus, a preferred method for denoising the received signal in the CDT domain is to first estimate σ² from a “noise only” portion of the received signal, and then apply Equation 6, or Equation 7 as the case may be, to determine the noise corrected CDF \tilde{S}_{g}(t) of the signal of interest. This effectively filters the noise from the received signal in the CDF domain. In practice, one may replace E[R(t)] by the estimated CDF of r(t) to get the estimate noise-free CDF, \tilde{S}_{g}(t).

Returning to FIG. 3, in S306 controller 202 analyzes the received signal to determine a “noise-only” portion. The “noise-only” portion may be selected by controller 202, in one embodiment, by analyzing the amplitude of the received signal and identifying a portion thereof whose amplitude is below a certain threshold. In S308, controller 202 estimates the variance in that “noise-only” portion of the received signal using a known estimator for noise variance. With the variance in hand, controller 202 can, in S310, determine the energy of the noise-free signal by subtracting σ²(t_{N}−t₁) from the calculated energy of the noisy received signal E_{z}_{_{η}}, determined by controller 202, as shown below (Equation 8).

ε_{z}=ε_{z}_{_{η}}−σ²(t_{N}−t₁)

This leaves E[R(t)] as the only remaining term necessary to solve Equation 6 for \tilde{S}_{g}(t). However, as mentioned above, one may replace E[R(t)] by the estimated CDF of r(t), which is done in S312. Controller 202 uses the following expression to calculate the CDF of r(t) (Equation 9).

$$R ( {t}_{k} ) = \frac{1}{{ɛ}_{{z}_{η}}} {\sum }_{i = 1}^{k} {( z ( {t}_{i} ) + η ( {t}_{i} ) )}^{2}$$

In S314, controller 202 estimates the CDF of the noise free signal of interest by Equation 6. However, in cases where obtaining the SNR is easier compared to obtaining the energy of the noise-free signal and the noise variance, Equation 7 may be used to calculate the CDF of the noise-free signal, where E[R(t)] is once again replaced by the estimated CDF of r(t) generated in S312.

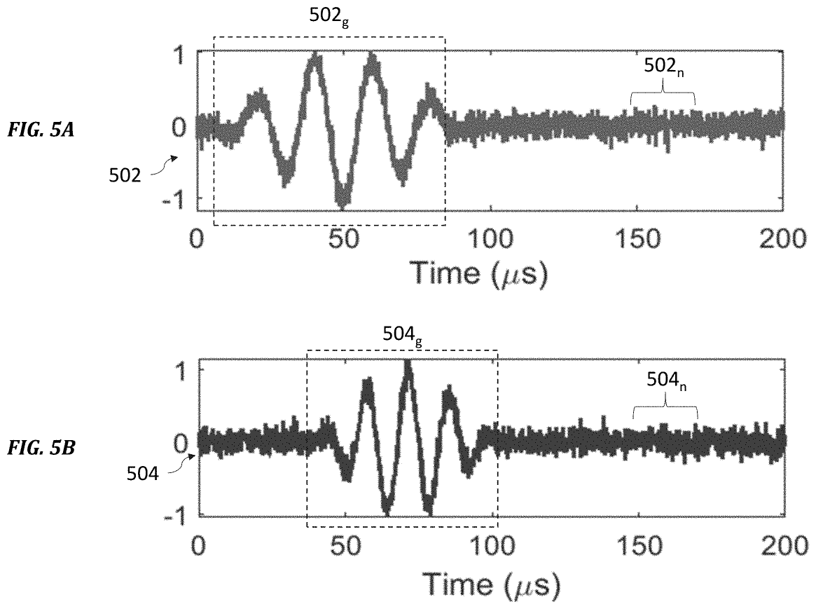

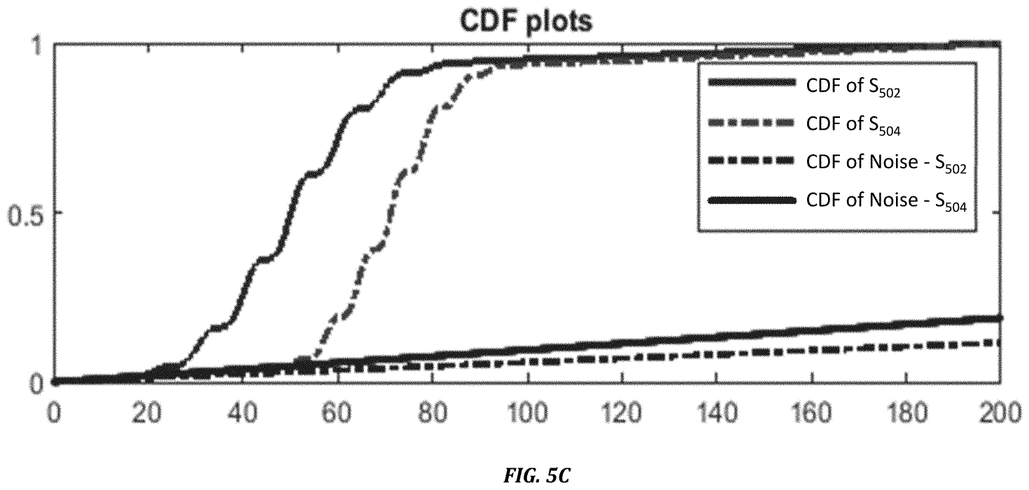

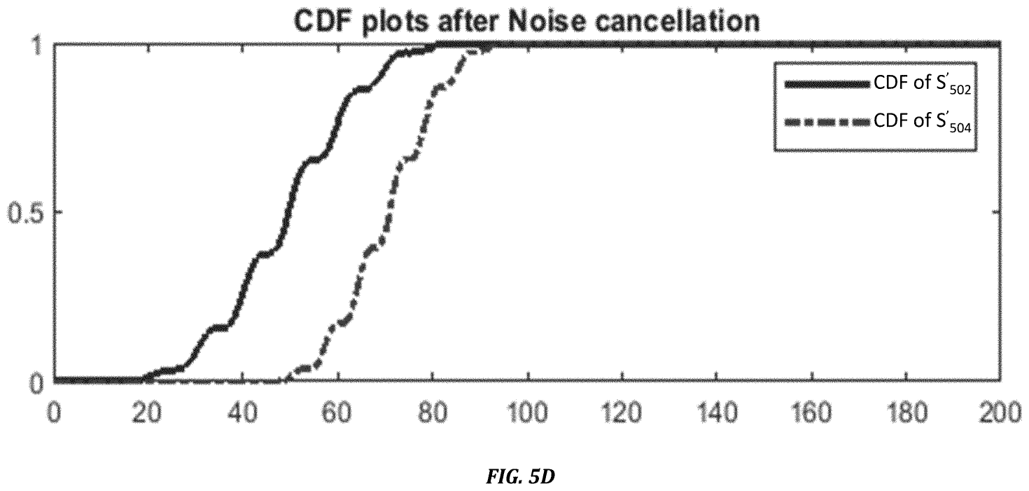

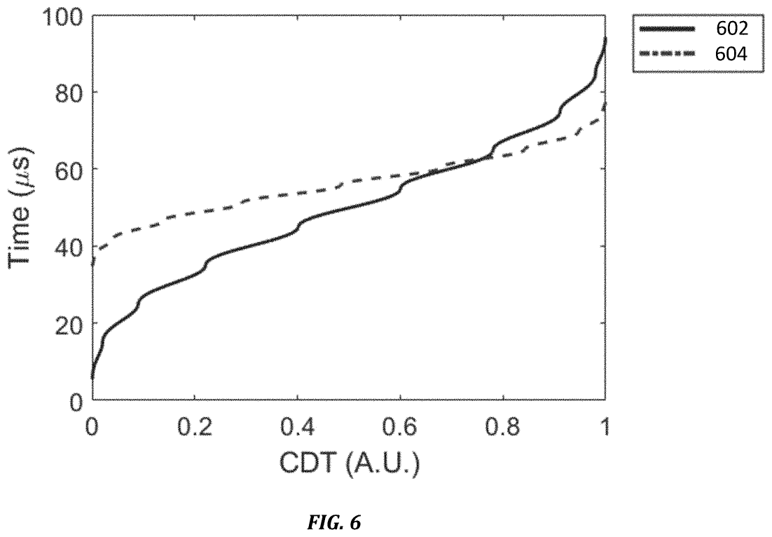

Having described how controller 202 processes a received signal, the process shown in FIG. 3 will be further illustrated in reference to FIGS. 5A-5D. FIGS. 5A and 5B are plots of two received signals 502 and 504 as a function of time. The two signals 502 and 504 are separated by a time delay of 35 microseconds. As is self-evident from FIGS. 5A and 5B, signals 502 and 504 contain significant noise, but also include signals of interest 502_{g} and 504_{g}, respectively. FIG. 5C is a plot of the CDFs of signal 502 and 504 (denoted S502 and S504 in FIG. 5C). Also shown are plots of the CDFs of noise present in signals 502 and 504 which is generated from noise-only portions 502ₙ and 504ₙ of signals 502 and 504. As can be seen from FIG. 5C, the CDFs of the noise-only portions 502ₙ and 504ₙ have constant slopes. Using the method outlined in FIG. 3, the CDF for the noise-free signal-of-interest \tilde{S}_{g}(t) is determined and the result is shown in FIG. 5D. In another embodiment, controller 202 may also be programmed to reconstruct the denoised signal in the time domain as the CDT is invertible.

Having described a process for obtaining a noise-corrected CDF of the signal-of-interest in a received signal, attention will now be directed to various applications of that noise-corrected CDF. As discussed above, the time delay between when two signals are received at a sensor can be used to locate the source of the signal. However, the medium 110, through which the signal travels, morphs the signal emitted by source 106. Conventional approaches to calculating time delays do not account for that morphing and, as demonstrated below, result in inaccurate estimations of the source location. Unlike the conventional approaches, controller 202 approaches the problem by considering how much a signal recorded by one of the sensors would have to change to make it equivalent to a signal recorded by another sensor, as a function of time delay. That process is described in U.S. patent application Ser. No. 16/905,842, the contents of which are incorporated by reference herein in their entirety. However, the '842 application does not entirely account for noise in the received signals in the source localization process, and thus by using the noise removal technique described above an even more accurate estimation of the source location may be obtained, as explained below.

For most physical systems, the medium 110 will act as a minimum energy transformation so the true delay between when two sensors receive a signal emitted by the source will coincide with a minimal 2-Wasserstein distance. As one of ordinary skill will appreciate, the Wasserstein metric or distance is a distance function defined between probability distributions on a given metric space. Intuitively, the Wasserstein distance can be understood as the cost of turning one pile of dirt into another pile of dirt. In terms of signals, the minimal Wasserstein distance represents the minimum amount of “effort” (quantified as signal intensity times distance) required to transform one signal into another signal.

It can be shown that the cost function, i.e. the Wasserstein distance, is given by Equations 10 and 11 below

W²(r_{f}, s)=ₕ^{inf}∫|h(u)−u|²s(u)du

W²(r_{f}, s)=∥gₚ∘\hat{r}−ŝ∥ₗ_{₂}²

In Equation 11, gₚ is a one-to-one continuous function with a parameter p, and \hat{r} and ŝ are CDTs corresponding to a first and second signal, respectively. Polynomials gₚ(t)=Σₖ₌₀^{K-1}pₖt^{k} of different degrees may be used in time delay estimation problem. This polynomial is able to capture events such as time delay and dispersion in the physics of wave propagation. Moreover, such a polynomial model of the transformation gₚ(t) is commonly used in many signal processing applications. In applications where gₚ(t) is unknown, polynomial approximations are often used to model the transformation.

Turning first to estimating time delays without accounting for dispersion, gₚ(t)=t−τ, the cost function given by Equation 11 becomes (Equation 12)

W²(r_{f}, s)=∥\hat{r}−τ−ŝ∥ₗ_{₂}²

The translation value τ that minimizes Equation 12 is then give by (Equation 13):

$$τ = \frac{1}{\vert {Ω}_{{s}_{0}} \vert} {\int }_{{Ω}_{{s}_{0}}} [ \hat{r} ( u ) - \hat{s} ( u ) ] d u$$

From Equation 13, one can estimate the delay as the difference in the average values of the CDTs \hat{r} and ŝ taken over the domain Ωₛ_{₀}=[0, 1]. As one of ordinary skill will appreciate, generating noise-free CDFs corresponding to signals r and s (as described above), which in turn are used to generate CDTs \hat{r} and ŝ, will yield a more accurate estimate of the time delay. In one embodiment, controller 202 is constructed to calculate the time delay between two received signals by computationally solving Equation 13 for the time delay by Equation 14 below.

$$\tilde{τ} = \frac{1}{N} {\sum }_{i = 1}^{N} ( \hat{r} ( {u}_{i} ) - \hat{s} ( {u}_{i} ) )$$

In Equation 14, the CDTs \hat{r} and ŝ are defined on the discrete grids

$${u}_{i} = \frac{i}{N} ,$$

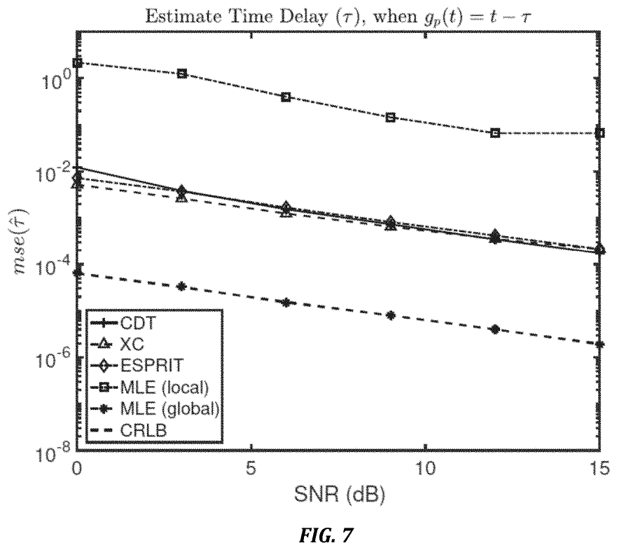

i=1 . . . N. These estimates can then be compared to those obtained by conventional techniques, such as cross-correlation estimation that is done in the time domain. To that end a simulation of 1000 realizations of a signal zₙ(t) for varying noise levels and a delay of τ=0.2575 seconds was performed. The linear dispersion was fixed at ω=1. To evaluate the performance of the above techniques, the mean square error (MSE) was computed and compared with a cross-correlation (XC) based estimator, maximum likelihood estimator (MLE) with both local and global solutions, and a subspace based method, the ESPRIT (estimation of signal parameters via rotational invariance techniques) based time delay estimation technique. The results for an increasing signal-to-noise ratio is shown in FIG. 7, along with the Cramer lower bound (CRLB). It is self-evident from FIG. 7 that the CDT-based technique for linear time delay estimation is at least as accurate as the time domain estimators. However, if one considers the case of joint estimation of time and linear dispersion, the increased efficiency of the CDT-based approach becomes clear.

In the joint estimation of time delay and linear dispersion we have that gₚ(t)=ωt−τ, thus gₚΩ\hat{r}=ω\hat{r}−τ, and thus the cost function becomes (Equation 15):

W²(r_{f}, s)=∥ω\hat{r}−τ−ŝ∥ₗ_{₂}²=∥α\hat{r}+β−ŝ∥ₗ_{₂}²

In Equation 15, it is clear that α=ω and β=−τ. This is also a linear least squares problem from which ω and τ can readily be recovered. The closed form solution to this problem is given by (Equation 16):

[\tilde{α}, \tilde{β}]^{T}=(X^{T}X)⁻¹X^{T}ŝ

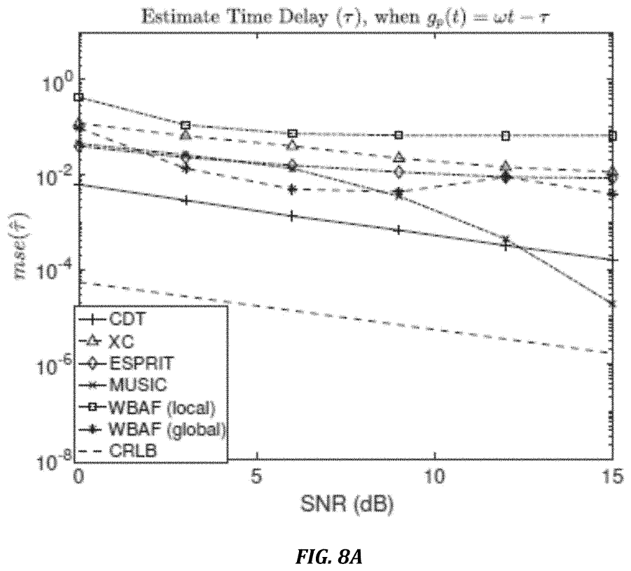

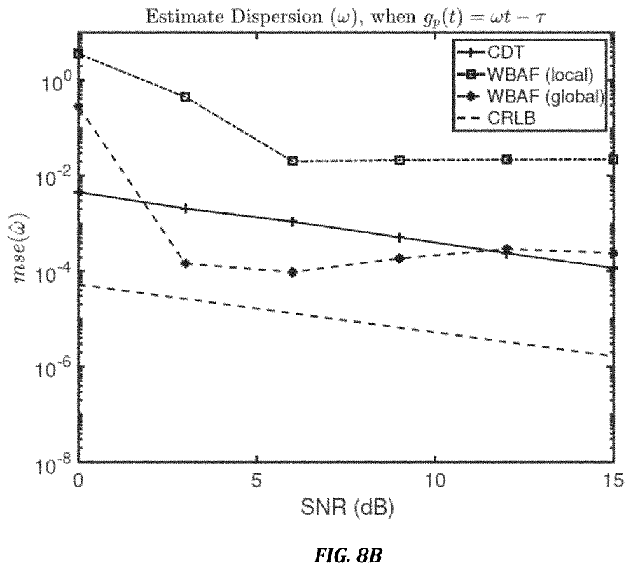

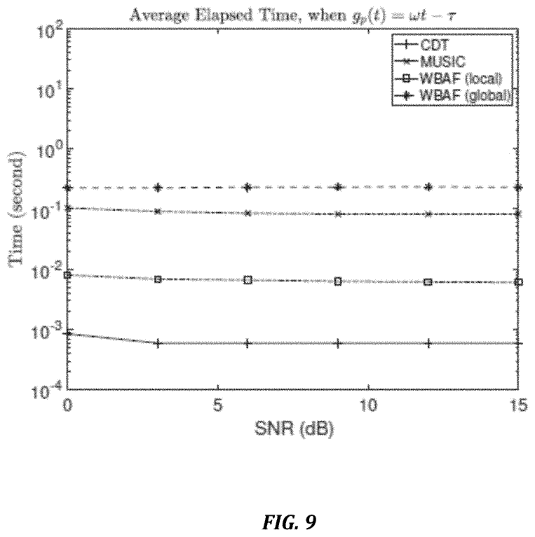

In Equation 16, X≡[\hat{\vec{r}}, \vec{1}] is an N×2 matrix. To show the greater efficiency of the CDT-based approach, a joint estimation problem for both time delay τ=0.2575 and linear dispersion (time scale) ω=0.75 was modeled. The MSE of the joint delay and linear dispersion estimates for different estimators are plotted in FIGS. 8A and 8B, respectively. For comparison, the cross-correlation and ESPRIT based estimators are used again to estimate the delay parameter only. In this case, both XC and ESPRIT estimators perform poorly as these techniques do not take linear dispersion into account. Another subspace based method, the MUSIC (multiple signal classification) algorithm is also shown, along with a Wide-band Ambiguity Function (WBAF) based estimator. As is self-evident from FIG. 8A, the CBT-based approach outperforms the other estimators with respect to time delay estimation and a local WBAF estimator for dispersion. FIG. 9 is a plot of elapsed time to reach a solution versus SNR for the CDT-based approach, the local and global WBAF estimators, and the MUSIC estimator. FIG. 9 shows that the CDT-based approach is orders of magnitude better than the other estimators. In other words, the CDT-based approach—based on noise-free CDFs of the signal of interest—yields at least as accurate, or better, estimations of time delay and dispersion than conventional estimators—in orders of magnitude less time. As explained above, what the particular signals are and what task is being solved is, in general, irrelevant as the noise removal techniques described herein provide a software based improvement to the speed and efficiency of the computer processing those signals.

While various example embodiments of the invention have been described above, it should be understood that they have been presented by way of example, and not limitation. It is apparent to persons skilled in the relevant art(s) that various changes in form and detail can be made therein. Thus, the disclosure should not be limited by any of the above described example embodiments, but should be defined only in accordance with the following claims and their equivalents.

In addition, it should be understood that the figures are presented for example purposes only. The architecture of the example embodiments presented herein is sufficiently flexible and configurable, such that it may be utilized and navigated in ways other than that shown in the accompanying figures.

Further, the purpose of the Abstract is to enable the U.S. Patent and Trademark Office and the public generally, and especially the scientists, engineers and practitioners in the art who are not familiar with patent or legal terms or phraseology, to determine quickly from a cursory inspection the nature and essence of the technical disclosure of the application. The Abstract is not intended to be limiting as to the scope of the example embodiments presented herein in any way. It is also to be understood that the procedures recited in the claims need not be performed in the order presented.

What is claimed is:

1. A method, comprising:
receiving, at a controller, a signal recorded by a sensor and emitted by a source that includes a signal of interest component and a noise component;
sampling the noise component of the signal;
estimating a variance in the sampled noise component of the signal;
determining an energy of the signal of interest component of the signal;
calculating a cumulative distribution function for the received signal;
calculating a cumulative distribution function of the signal of interest component of the received signal based on the estimated variance in the sampled noise component, the determined energy of the signal of interest component of the signal, and the calculated cumulative distribution function for the received signal.
